(19) United States
(12) Patent Application Publication
(10) Pub. No.: US 2007/0254494 A1
(43) Pub. Date: Nov. 1, 2007

(54) Faceplate with rapid temperature change

(75) Inventors: Harald Herchen, Los Altos, CA (US); Lue C. Brian, Mountain View, CA (US); Quach H. David, San Jose, CA (US); Anzhong Chang, San Jose, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 11/414,728

(22) Filed: Apr. 27, 2006

(51) Int. Cl. F27D 3/00; H01L 21/00

(52) U.S. Cl. 438/795; 432/121

(57) ABSTRACT

The present invention relates to a thermal unit comprising a faceplate with rapid temperature change capabilities. The methods and components of the present invention may be used in post-exposure bake processes where varied temperatures are used. In accordance with the advantages of the present invention, the thermal units and faceplates of the invention can reach temperature equilibration within a short duration of time, thereby allowing quicker processing times. The faceplates of the invention are configured so as achieve a heat up and cool down temperature delta equilibrium with a bakeplate within a semiconductor thermal unit in, e.g., less than about three minutes, each respectively. In certain aspects, the faceplate includes a mesh disk with holes configured to allow for passive diffusion of gases, and a mounting ring located about the exterior perimeter of the mesh disk configured to support and secure the mesh disk to ensure that the mesh disk maintains its shape over the full operating temperature range of the thermal unit including the faceplate.

### BACKGROUND OF THE INVENTION

The present invention relates generally to the field of substrate processing equipment. More particularly, the present invention relates to a faceplate for use with thermal units of semiconductor substrate processing equipment.

Modern integrated circuits contain millions of individual elements that are formed by patterning the materials, such as silicon, metal and/or dielectric layers, which make up the integrated circuit, to sizes that are small fractions of a micrometer. The technique used throughout the industry for forming such patterns is photolithography. A typical photolithography process sequence generally includes depositing one or more uniform photoresist (resist) layers on the surface of a substrate, drying and curing the deposited layers, patterning the substrate by exposing the photoresist layer to electromagnetic radiation that is suitable for modifying the exposed layer, and then developing the patterned photoresist layer.

It is common in the semiconductor industry for many of the steps associated with the photolithography process to be performed in a multi-chamber processing system (e.g., a cluster tool) that has the capability to sequentially process semiconductor wafers in a controlled manner. One example of a cluster tool that is used to deposit (i.e., coat) and develop a photoresist material is commonly referred to as a track lithography tool.

Track lithography tools typically include a mainframe that houses multiple chambers (which are sometimes referred to herein as stations) dedicated to performing the various tasks associated with pre- and post-lithography processing. There are typically both wet and dry processing chambers within track lithography tools. Wet chambers include coat and/or develop bowls, while dry chambers include thermal control units that house bake and/or chill plates. Track lithography tools also frequently include one or more pod/cassette mounting devices, such as an industry standard FOUP (front opening unified pod), to receive substrates from and return substrates to the clean room, multiple substrate transfer robots to transfer substrates between the various chambers/stations of the track tool, and an interface that allows the tool to be operatively coupled to a lithography exposure tool in order to transfer substrates into the exposure tool and receive substrates from the exposure tool after the substrates are processed within the exposure tool.

Often, various chambers of track lithography tools require the performance of processing steps at varied temperatures, depending on the nature of the device being manufactured. However, traditional designs have shortcomings that result in limitations in terms of, e.g., turn-around times between temperature changes.

### BRIEF SUMMARY OF THE INVENTION

In part to address such shortcomings, in a first aspect the present invention provides a faceplate with rapid temperature equilibration for use in a semiconductor thermal unit. The faceplate generally includes: a mesh disk with holes configured to allow for passive diffusion of gases; and a mounting ring located about the exterior perimeter of the mesh disk configured to support and secure the mesh disk to ensure that the mesh disk maintains its shape over the full operating temperature range. In accordance with certain embodiments; the mesh disk is formed from a material having a specific thermal mass less than about 500 J/m²-K so as to allow for rapid temperature equilibration of the faceplate. In other embodiments, the mesh disk is between about 125 μm and about 250 μm in thickness.

In certain aspects, the mesh disk is configured so as achieve a heat up and cool down temperature delta equilibrium with the bakeplate within the semiconductor thermal unit in less than about three minutes, each respectively.

In other aspects, the mesh disk comprises a lattice of reinforcing fibers held in tension by the mounting ring, thereby providing structural support for the faceplate without the need for self-supporting shear strength and/or modulus of the disk material.

In another aspect of the invention, a semiconductor thermal unit for use in post-exposure bake processing is provided. The thermal unit generally includes: a bakeplate configured to support a wafer and heat the wafer during post-exposure bake processing; a lid configured to interface with the bakeplate so as to enclose a bake chamber for post-exposure bake processing; and a faceplate of the invention located between the bakeplate and the lid, configured to be located above the position of a wafer located on the bakeplate so as to allow for the passive diffusion of solvent from the wafer through the faceplate to thereby prevent condensation of solvents back onto the wafer during post-exposure bake processing. The faceplate

In yet another aspect of the invention, a track lithography tool comprising semiconductor thermal unit of the invention for use in post-exposure bake processing is provided.

In yet another aspect of the invention, a method for performing multiple post-exposure bake processes in a single semiconductor thermal unit is provided, wherein at least one of the post-exposure bake processes is performed at a temperature which differs from the other post-exposure bake processes. The method generally includes: providing a semiconductor thermal unit of the invention; locating a first semiconductor wafer within a semiconductor thermal unit for a post-exposure bake process; performing a first post-exposure bake process in the semiconductor thermal unit at a first temperature; removing the first semiconductor wafer from the semiconductor thermal unit; modifying the set-point temperature of the semiconductor thermal unit to a second temperature and allowing the semiconductor thermal unit to reach temperature equilibrium such that the faceplate and the bakeplate of the semiconductor thermal unit to reach a temperature delta equilibrium within about three minutes; and performing a second post-exposure bake process in the semiconductor thermal unit at the second temperature.

These and other aspects of the invention will be described in more detail throughout the present specification and more particularly below in conjunction with the following drawings.

### BRIEF DESCRIPTION OF THE DRAWINGS

FIG. 1 is a simplified plan view of an embodiment of a track lithography tool according to an embodiment of the present invention;

FIG. 2 is an front perspective view of a semiconductor thermal unit according to an embodiment of the present invention;

FIG. 3 is a top view of a faceplate according to an embodiment of the present invention;

FIG. 4 is a cross-section side view of a faceplate of FIG. 3 according to an embodiment of the present invention;

FIG. 5 is flow diagram of an exemplary method for performing multiple post-exposure bake processes in a single semiconductor thermal unit according to an embodiment of the present invention.

### DETAILED DESCRIPTION OF THE INVENTION

According to the present invention, techniques related to the field of substrate processing equipment are provided. More particularly, the present invention relates to a thermal unit comprising a faceplate with rapid temperature change capabilities. Merely by way of example, the methods and components of the present invention may be used in post-exposure bake processes where varied temperatures are used. In accordance with the advantages of the present invention, the thermal units and faceplates of the invention can reach temperature equilibration within a short duration of time, thereby allowing quicker processing times. The method and apparatus can be applied to other processes for semiconductor substrates, for example those used in pre-exposure bake processing, post-resist bake processing, etc.

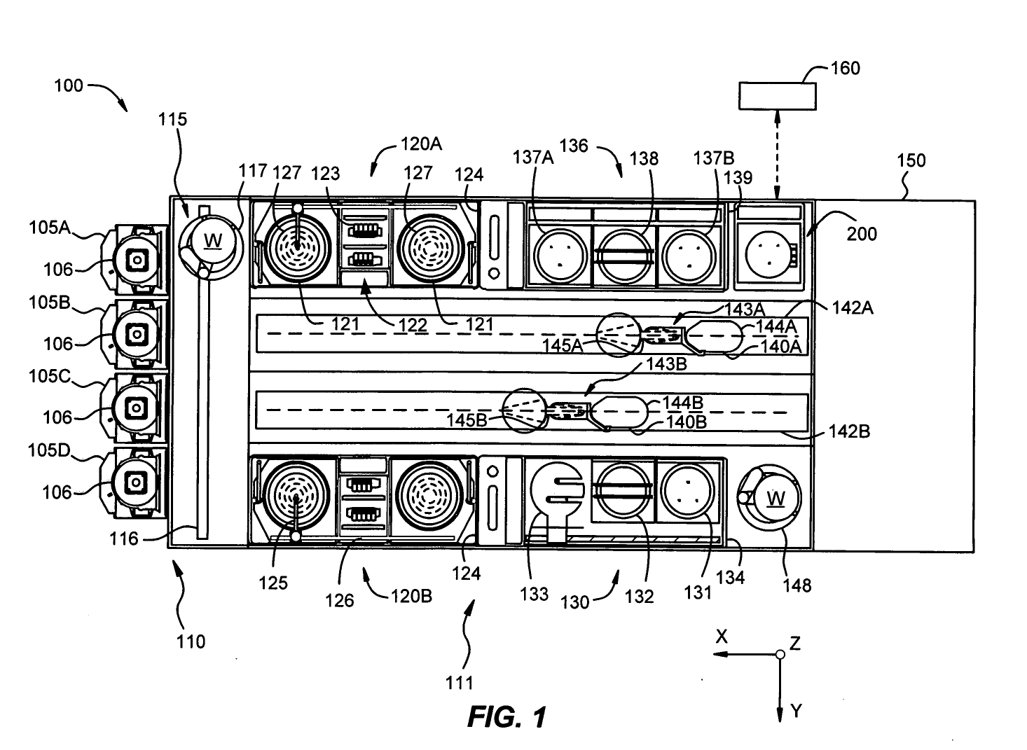

FIG. 1 is a plan view of an embodiment of a track lithography tool 100 in which the embodiments of the present invention may be used. As illustrated in FIG. 1, track lithography tool 100 contains a front end module 110 (sometimes referred to as a factory interface or FI) and a process module 111. In other embodiments, the track lithography tool 100 includes a rear module (not shown), which is sometimes referred to as a scanner interface. Front end module 110 generally contains one or more pod assemblies or FOUPS (e.g., items 105A-D) and a front end robot assembly 115 including a horizontal motion assembly 116 and a front end robot 117. The front end module 110 may also include front end processing racks (not shown). The one or more pod assemblies 105A-D are generally adapted to accept one or more cassettes 106 that may contain one or more substrates or wafers, “W,” that are to be processed in track lithography tool 100. The front end module 110 may also contain one or more pass-through positions (not shown) to link the front end module 110 and the process module 111.

Process module 111 generally contains a number of processing racks 120A, 120B, 130, and 136. As illustrated in FIG. 1, processing racks 120A and 120B each include a coater/developer module with shared dispense 124. A coater/developer module with shared dispense 124 includes two coat bowls 121 positioned on opposing sides of a shared dispense bank 122, which contains a number of nozzles 123 providing processing fluids (e.g., bottom anti-reflection coating (BARC) liquid, resist, developer, and the like) to a wafer mounted on a substrate support 127 located in the coat bowl 121. In the embodiment illustrated in FIG. 1, a dispense arm 125 sliding along a track 126 is able to pick up a nozzle 123 from the shared dispense bank 122 and position the selected nozzle over the wafer for dispense operations. Of course, coat bowls with dedicated dispense banks are provided in alternative embodiments.

Processing rack 130 includes an integrated thermal unit 134 including a bake plate 131, a chill plate 132, and a shuttle 133. The bake plate 131 and the chill plate 132 are utilized in heat treatment operations including post exposure bake (PEB), post-resist bake, and the like. In some embodiments, the shuttle 133, which moves wafers in the x-direction between the bake plate 131 and the chill plate 132, is chilled to provide for initial cooling of a wafer after removal from the bake plate 131 and prior to placement on the chill plate 132. Moreover, in other embodiments, the shuttle 133 is adapted to move in the z-direction, enabling the use of bake and chill plates at different z-heights. Processing rack 136 includes an integrated bake and chill unit 139, with two bake plates 137A and 137B served by a single chill plate 138.

One or more robot assemblies (robots) 140 are adapted to access the front-end module 110, the various processing modules or chambers retained in the processing racks 120A, 120B, 130, and 136, and the scanner 150. By transferring substrates between these various components, a desired processing sequence can be performed on the substrates. The two robots 140 illustrated in FIG. 1 are configured in a parallel processing configuration and travel in the x-direction along horizontal motion assembly 142. Utilizing a mast structure (not shown), the robots 140 are also adapted to move in a vertical (z-direction) and horizontal directions, i.e., transfer direction (x-direction) and a direction orthogonal to the transfer direction (y-direction). Utilizing one or more of these three directional motion capabilities, robots 140 are able to place wafers in and transfer wafers between the various processing chambers retained in the processing racks that are aligned along the transfer direction.

Referring to FIG. 1, the first robot assembly 140A and the second robot assembly 140B are adapted to transfer substrates to the various processing chambers contained in the processing racks 120A, 120B, 130, and 136. In one embodiment, to perform the process of transferring substrates in the track lithography tool 100, robot assembly 140A and robot assembly 140B are similarly configured and include at least one horizontal motion assembly 142, a vertical motion assembly 144, and a robot hardware assembly 143 supporting a robot blade 145. robot assemblies 140 are in communication with a system controller 160. In the embodiment illustrated in FIG. 1, a rear robot assembly 148 is also provided.

The scanner 150, which may be purchased from Canon USA, Inc. of San Jose, Calif., Nikon Precision Inc. of Belmont, Calif., or ASML US, Inc. of Tempe Ariz., is a lithographic projection apparatus used, for example, in the manufacture of integrated circuits (ICs). The scanner 150 exposes a photosensitive material (resist), deposited on the substrate in the cluster tool, to some form of electromagnetic radiation to generate a circuit pattern corresponding to an individual layer of the integrated circuit (IC) device to be formed on the substrate surface.

Each of the processing racks 120A, 120B, 130, and 136 contain multiple processing modules in a vertically stacked arrangement. That is, each of the processing racks may contain multiple stacked coater/developer modules with shared dispense 124, multiple stacked integrated thermal units 134, multiple stacked integrated bake and chill units 139, or other modules that are adapted to perform the various processing steps required of a track photolithography tool. As examples, coater/developer modules with shared dispense 124 may be used to deposit a bottom antireflective coating (BARC) and/or deposit and/or develop photoresist layers. Integrated thermal units 134 and integrated bake and chill units 139 may perform bake and chill operations associated with hardening BARC and/or photoresist layers after application or exposure.

In one embodiment, a system controller 160 is used to control all of the components and processes performed in the cluster tool 100. The controller 160 is generally adapted to communicate with the scanner 150, monitor and control aspects of the processes performed in the cluster tool 100, and is adapted to control all aspects of the complete substrate processing sequence. The controller 140, which is typically a microprocessor-based controller, is configured to receive inputs from a user and/or various sensors in one of the processing chambers and appropriately control the processing chamber components in accordance with the various inputs and software instructions retained in the controller's memory. The controller 140 generally contains memory and a CPU (not shown) which are utilized by the controller to retain various programs, process the programs, and execute the programs when necessary. The memory (not shown) is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits (not shown) are also connected to the CPU for supporting the processor in a conventional manner. The support circuits may include cache, power supplies, clock circuits, input/output circuitry, subsystems, and the like all well known in the art. A program (or computer instructions) readable by the controller 140 determines which tasks are performable in the processing chamber(s). Preferably, the program is software readable by the controller 160 and includes instructions to monitor and control the process based on defined rules and input data.

It is to be understood that embodiments of the invention are not limited to use with a track lithography tool such as that depicted in FIG. 1. Instead, embodiments of the invention may be used in any track lithography tool including the many different tool configurations described in U.S. patent application Ser. No. 11/315,984, entitled “Cartesian Robot Cluster Tool Architecture” filed on Dec. 22, 2005, which is hereby incorporated by reference for all purposes and including configurations not described in the above referenced application.

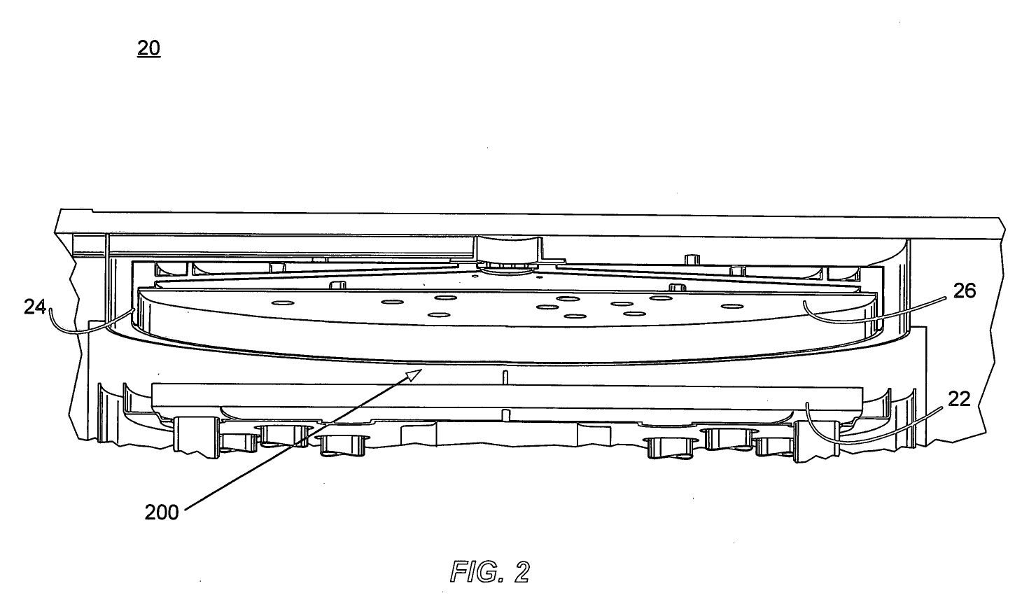

Turning now to specific thermal units in accordance with certain aspects of the present invention, FIG. 2 illustrates a front perspective view of an exemplary semiconductor thermal unit that may be used, e.g., for post-exposure bake (PEB) processing. However, the thermal units and associated components are not limited to PEB processing. The thermal unit 20 generally includes bakeplate 22, lid 24, and faceplate 26. In use, bakeplate 22 is configured to support wafer (not shown), and to heat the wafer, e.g., during post-exposure bake processing. As understood by those skilled in the art, bakeplate 22, and optionally lid 24, will include controllable heater elements (not shown) to controllably heat a semiconductor wafer (not shown) to desired set-point temperatures. Further, as illustrated, lid 24 is configured to interface with bakeplate 22 so as to enclose bake chamber 200 for, e.g., post-exposure bake processing.

Faceplate 26 is located between bakeplate 22 and lid 24. Bake chamber 200 is configured such that faceplate 26 is located above the position of a semiconductor wafer (not shown) located on bakeplate 22. Faceplate 26 is positioned so as to allow for the passive diffusion of solvent from a semiconductor wafer (not shown) through faceplate 26 to thereby prevent condensation of solvents back onto the wafer during, e.g., post-exposure bake processing.

The faceplate 26 is ultra thin compared to standard faceplates known in the art. Standard faceplates used in typical thermal units are made of metal and thick enough to support their own weight. While not being limited by theory, in accordance with certain aspects of the invention, an advantage of the ultra-thin faceplates of the invention is that the thermal mass of such faceplates is significantly below that of a standard faceplate. For example, a standard faceplate is about 3 mm thick, made of stainless steel, with a specific thermal mass of about 3500 J/m²-K. Such configurations take dozens of minutes to cool in air. In contrast, the faceplates of the present invention generally have a thermal mass that is reduced by a factor of 30 or more, reducing the time to reach temperature equilibration with the ambient air, and/or equilibrate the temperature delta with the bakeplate of the thermal unit, by a similar factor. This ability to change temperature more quickly is a significant advantage when needing to change the temperature of a thermal unit during processing.

By way of example, the faceplates of the invention are configured so as achieve a heat up and cool down temperature delta equilibrium with a bakeplate within a semiconductor thermal unit in, e.g., less than about three minutes, each respectively (i.e., heat up and cool down temperature delta equilibrium). Temperature delta equilibrium may be based on the difference between (current and final faceplate temperature delta) and (current and final bakeplate temperature delta).

The faceplate may have fiber reinforcement in it, possibly of low or negative thermal expansion coefficient strong material such as Kevlar or similar material. The reinforcement is mounted in tension, providing strong support for the faceplate without the need of shear strength and modulus of state of the art diffusers.

The faceplate is surrounded and mounted in a ring made of low thermal expansion coefficient, to ensure that the reinforcing fibers stay taut, over the full operating temperature range. Alternately, the faceplate may be surrounded by a high thermal expansion coefficient but compressible material, so that at all temperatures, the faceplate remains taut and essentially flat.

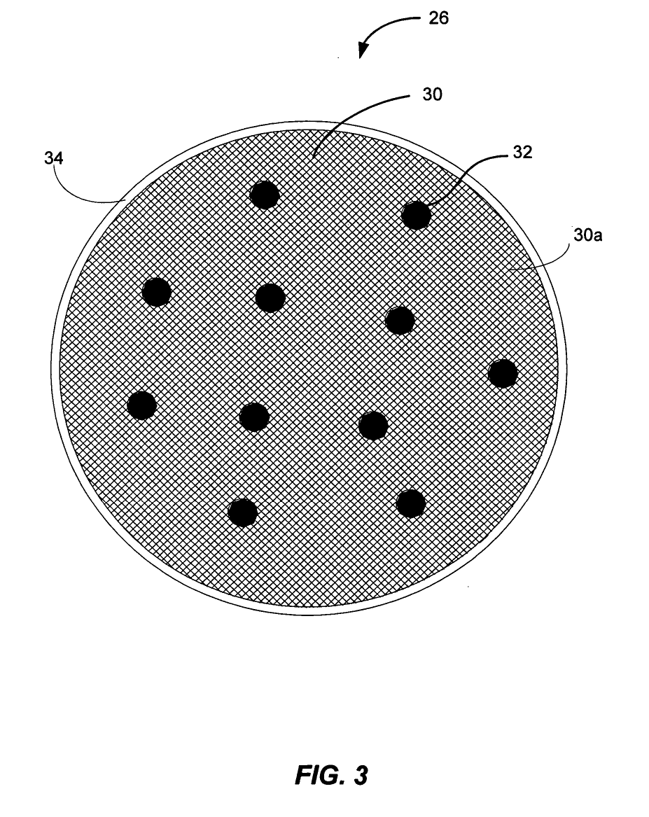

More specifically, with reference to FIG. 3, a top view of an exemplary faceplate 26 in accordance with certain aspects of the invention is shown. As illustrated, faceplate 26 comprises a mesh disk 30 with holes 32 configured to allow for passive diffusion of gases, and a mounting ring 34 located about the exterior perimeter of the mesh disk 30 configured to support and secure the mesh disk 30 to ensure that the mesh disk 30 maintains its shape over the full operating temperature range of the thermal unit. The mesh disk 30 includes a lattice of reinforcing fibers 30a held in tension by the mounting ring 34, thereby providing structural support for the faceplate without the need for self-supporting shear strength and/or modulus of the disk material.

The mesh disk may also be configured so as achieve a heat up and cool down temperature delta equilibrium with a bakeplate within a semiconductor thermal unit in, e.g., less than about three minutes, each respectively (i.e., heat up and cool down temperature delta equilibrium). In certain embodiments, the mesh disk may include structural ribs (not shown) configured to prevent warping during temperature changes.

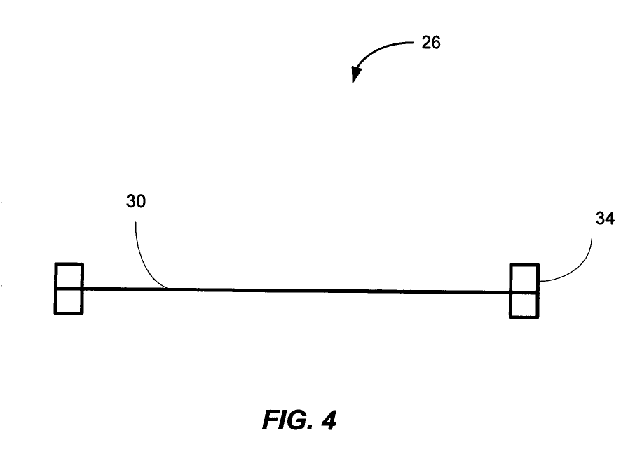

Further, with reference to FIG. 4, a cross-section of the faceplate 26 of FIG. 3 is illustrated. Mesh disk 30 and mounting ring 34 are shown in FIG. 4, with the thin profile of the mesh disk 30 illustrated. By way of example, in certain embodiments the mesh disk is between about 100 μm to about 300 μm, about 125 μm to about 250 μm, or about 130 μm to about 200 μm in thickness.

In accordance with certain embodiments of the present invention, the mesh disk is formed from a material having a specific thermal mass of less than about 500 J/m²-K, or in other embodiments of less than about 300 J/m²-K, e.g., in the range of about 100 J/m²-K to about 300 J/m²-K, or in the range of about 150 J/m²-K to about 250 J/m²-K, so as to allow for rapid temperature equilibration (e.g., in less than about 5 minutes to about 3 minutes) of the faceplate during temperature change operations of the thermal unit. As used herein, specific thermal mass is a measure of the thermal energy needed to raise a unit mass by one Kelvin.

The mesh disk may be formed from any suitable low specific thermal mass material known in the art. By way of non-limiting example, the mesh disk may be comprised of corrugated aluminum foil or polyimide sandwiched over Kevlar® mesh. More particularly, the mesh disk may be comprised a lattice of reinforcing poly-paraphenylene terephthalamide fibers coated with polyimide. In yet other embodiments, the mesh disk may be comprised of a lattice of reinforcing carbon epoxy fibers. More particularly, the mesh disk may be formed from TORAYCA® carbon fiber using the PAN (polyacrylonitrile) process, obtained from Toray Carbon Fibers America, Inc., and bonded together with a high temperature epoxy such as EP41A from MasterBond, to forma carbon fiber composite.

In certain embodiments, the mounting ring may be formed of low thermal expansion coefficient material, e.g., in the range of about 1 to about 8 ppm/K, less than about 5 ppm/K, or less than about 3 ppm/K. By way of example, the mounting ring may be comprised of Invar™ (i.e., a nickel-iron alloy), quartz, silicon, or silicon carbide, or similar material. In other embodiments, the mounting ring may be comprised of a compressible material having a high thermal expansion coefficient material of greater than, e.g., between about 10 ppm/K to about 20 ppm/K. In certain embodiments, the same material may be used for the mounting ring and the mesh disk, e.g., the mounting ring may be formed from a carbon fiber composite, with the same epoxy and composition as the mesh disk.

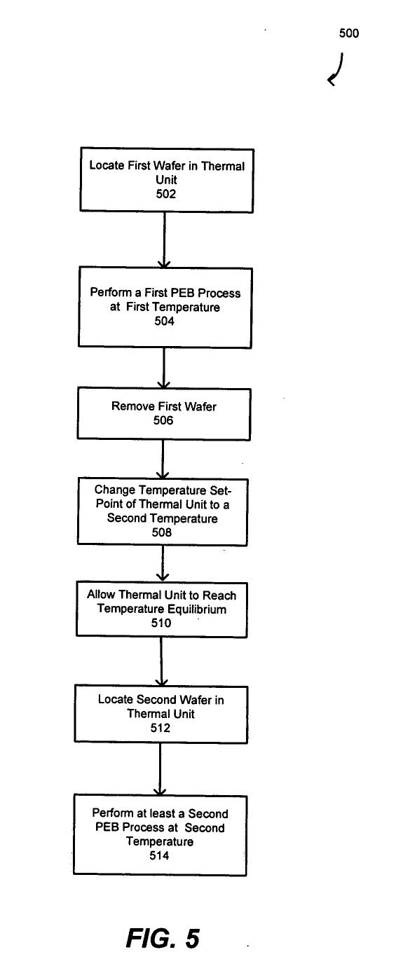

With reference to FIG. 5, yet other embodiments of the invention relate to methods 500 for performing multiple, e.g., post-exposure bake processes in a single semiconductor thermal units described herein, wherein at least one of the post-exposure bake processes is performed at a temperature which differs from the other post-exposure bake processes. Such methods will generally include locating a first semiconductor wafer within a semiconductor thermal unit of the invention for a post-exposure bake process 502 and performing a first post-exposure bake process in the semiconductor thermal unit at a first temperature 504. Following the first post-exposure bake process, the first semiconductor wafer is removed from the semiconductor thermal unit 506 and the set-point temperature of the semiconductor thermal unit is modified to a second temperature 508. The semiconductor thermal unit is then allowed to reach temperature equilibrium such that the faceplate and the bakeplate of the semiconductor thermal unit reach a temperature delta equilibrium within about three minutes in accordance with the invention 510. Once the thermal unit is at temperature equilibrium, a second semiconductor wafer is located within the thermal unit 512, and at least a second post-exposure bake process is performed in the semiconductor thermal unit at the second temperature 514.

Additional post-exposure bake process may optionally be performed at, e.g., the first temperature prior to changing the set point, at the second temperature, at a third temperature, forth temperature, etc. Further, as above, the method may be used to perform other types of bake processes, and is not limited to post-exposure bake processes. For example, the method may be used in pre-exposure bake processing, post-resist bake processing, etc.

### EXAMPLES

The following examples are provided to illustrate how the general faceplate and systems described in connection with the present invention may be used rapid temperature equilibration. However, the invention is not limited by the described examples.

Goal: 3 Minute Temperature Change Time on Faceplate

Tested three faceplates: (A) Corrugated Al foil (37 micron material); (B) Standard Flat SS plate (1000 micron thick); Bake chamber used with no cooling water delivered to chamber or lid; Temperature monitored via IR temperature sensor through window at top of lid; Results shown in charts below.

[image]

[image]

The examples and embodiments described herein are for illustrative purposes only. Various modifications or changes in light thereof will be suggested to persons skilled in the art and are to be included within the spirit and purview of this application and scope of the appended claims. It is not intended that the invention be limited, except as indicated by the appended claims.

What is claimed is:

1. A faceplate with rapid temperature equilibration for use in a semiconductor thermal unit, the faceplate comprising:
a mesh disk with holes configured to allow for passive diffusion of gases; and
a mounting ring located about the exterior perimeter of the mesh disk configured to support and secure the mesh disk to ensure that the mesh disk maintains its shape over the full operating temperature range;
wherein the mesh disk is formed from a material having a specific thermal mass of less than about 500 J/m²-K so as to allow for rapid temperature equilibration of the faceplate.

2. The faceplate of claim 1, wherein mesh disk is configured so as achieve a heat up and cool down temperature delta equilibrium with the bakeplate within the semiconductor thermal unit in less than about three minutes, each respectively.

3. The faceplate of claim 1, wherein mesh disk is between about 125 μm and about 250 μm in thickness.

4. The faceplate of claim 1, wherein the mesh disk comprises a lattice of reinforcing fibers held in tension by the mounting ring, thereby providing structural support for the faceplate without the need for self-supporting shear strength and/or modulus of the disk material.

5. The faceplate of claim 1, wherein mesh disk comprises lattice of reinforcing carbon epoxy fibers with spaced holes for passive diffusion of gases.

6. The faceplate of claim 1, wherein mesh disk comprises a lattice of reinforcing poly-paraphenylene terephthalamide fibers coated with polyimide, and having spaced holes for passive diffusion of gases.

7. The faceplate of claim 1, wherein mesh disk comprises ribs configured to prevent warping during temperature changes.

8. The faceplate of claim 1, wherein the mounting ring comprises a material having low thermal expansion coefficient between about 1 ppm/K and about 8 ppm/K.

9. The faceplate of claim 1, wherein the mounting ring comprises a compressible material having a high thermal expansion coefficient material between about 10 ppm/K and about 20 ppm/K.

10. The faceplate of claim 1, wherein the mounting ring comprises a nickel-iron alloy, quartz, silicon, silicon carbide, or carbon composite.

11. A semiconductor thermal unit for use in post-exposure bake processing, the thermal unit comprising:
a bakeplate configured to support a wafer and heat the wafer during post-exposure bake processing;
a lid configured to interface with the bakeplate so as to enclose a bake chamber for post-exposure bake processing; and
a faceplate located between the bakeplate and the lid, configured to be located above the position of a wafer located on the bakeplate so as to allow for the passive diffusion of solvent from the wafer through the faceplate to thereby prevent condensation of solvents back onto the wafer during post-exposure bake processing;
wherein the faceplate comprises a mesh disk with holes configured to allow for passive diffusion of gases, and a mounting ring located about the exterior perimeter of the mesh disk configured to support and secure the mesh disk to ensure that the mesh disk maintains its shape over the full operating temperature range; and wherein the mesh disk is formed from a material having a specific thermal mass of less than about 500 J/m²-K so as to allow for rapid temperature equilibration of the faceplate.

12. The semiconductor thermal unit of claim 11, wherein mesh disk is configured so as achieve a heat up and cool down temperature delta equilibrium with the bakeplate within the semiconductor thermal unit in less than about three minutes, each respectively.

13. The semiconductor thermal unit of claim 11, wherein mesh disk is between about 125 μm and about 250 μm in thickness.

14. The semiconductor thermal unit of claim 11, wherein the mesh disk comprises a lattice of reinforcing fibers held in tension by the mounting ring, thereby providing structural support for the faceplate without the need for self-supporting shear strength and/or modulus of the disk material.

15. A track lithography tool comprising semiconductor thermal unit for use in post-exposure bake processing, the thermal unit comprising:
a bakeplate configured to support a wafer and heat the wafer during post-exposure bake processing;
a lid configured to interface with the bakeplate so as to enclose a bake chamber for post-exposure bake processing; and
a faceplate located between the bakeplate and the lid, configured to be located above the position of a wafer located on the bakeplate so as to allow for the passive diffusion of solvent from the wafer through the faceplate to thereby prevent condensation of solvents back onto the wafer during post-exposure bake processing;
wherein the faceplate comprises a mesh disk with holes configured to allow for passive diffusion of gases, and a mounting ring located about the exterior perimeter of the mesh disk configured to support and secure the mesh disk to ensure that the mesh disk maintains its shape over the full operating temperature range; and wherein the mesh disk is formed from a material having a specific thermal mass of less than about 500 J/m²-K so as to allow for rapid temperature equilibration of the faceplate.

16. The track lithography tool of claim 15, wherein mesh disk is configured so as achieve a heat up and cool down temperature delta equilibrium with the bakeplate within the semiconductor thermal unit in less than about three minutes, each respectively.

17. The track lithography tool of claim 15, wherein mesh disk is between about 125 μm and about 250 μm in thickness.

18. The track lithography tool of claim 15, wherein the mesh disk comprises a lattice of reinforcing fibers held in tension by the mounting ring, thereby providing structural support for the faceplate without the need for self-supporting shear strength and/or modulus of the disk material.

19. A method for performing multiple post-exposure bake processes in a single semiconductor thermal unit, wherein at least one of the post-exposure bake processes is performed at a temperature which differs from the other post-exposure bake processes, the method comprising:
providing a semiconductor thermal unit comprising:
a bakeplate configured to support a wafer and heat the wafer during post-exposure bake processing;
a lid configured to interface with the bakeplate so as to enclose a bake chamber for post-exposure bake processing; and
a faceplate located between the bakeplate and the lid, configured to be located above the position of a wafer located on the bakeplate so as to allow for the passive diffusion of solvent from the wafer through the faceplate to thereby prevent condensation of solvents back onto the wafer during post-exposure bake processing;
wherein the faceplate comprises a mesh disk with holes configured to allow for passive diffusion of gases, and a mounting ring located about the exterior perimeter of the mesh disk configured to support and secure the mesh disk to ensure that the mesh disk maintains its shape over the full operating temperature range; and wherein the mesh disk is formed from a material having a specific thermal mass of less than about 500 J/m²-K so as to allow for rapid temperature equilibration of the faceplate;
locating a first semiconductor wafer within a semiconductor thermal unit for a post-exposure bake process;
performing a first post-exposure bake process in the semiconductor thermal unit at a first temperature;
removing the first semiconductor wafer from the semiconductor thermal unit;
modifying the set-point temperature of the semiconductor thermal unit to a second temperature and allowing the semiconductor thermal unit to reach temperature equilibrium such that the faceplate and the bakeplate of the semiconductor thermal unit to reach a temperature delta equilibrium within about three minutes;
locating a second semiconductor wafer within the semiconductor thermal unit for a post-exposure bake process; and
performing at least a second post-exposure bake process in the semiconductor thermal unit at the second temperature.

20. The method of claim 19, wherein mesh disk is between about 125 μm and about 250 μm in thickness.

21. The method of claim 19, wherein the mesh disk comprises a lattice of reinforcing fibers held in tension by the mounting ring, thereby providing structural support for the faceplate without the need for self-supporting shear strength and/or modulus of the disk material.
